(19) United States
(12) Patent Application Publication
(10) Pub. No.: US 2025/0140664 A1
(43) Pub. Date: May 1, 2025

(54) ELECTRONIC COMPONENT-INCORPORATING SUBSTRATE

(71) Applicant: SHINKO ELECTRIC INDUSTRIES CO., LTD., Nagano-shi (JP)

(72) Inventor: Shinichiro SEKIJIMA, Nagano-shi (JP)

(21) Appl. No.: 18/926,683

(22) Filed: Oct. 25, 2024

(30) Foreign Application Priority Data
Oct. 30, 2023 (JP) 2023-185341

(51) Int. Cl. H01L 23/498; H01L 23/00; H01L 23/31

(52) U.S. Cl. CPC H01L 23/49811; H01L 23/3107; H01L 23/49833; H01L 23/49866; H01L 24/16; H01L 24/32; H01L 24/73; H01L 2224/16227; H01L 2224/32225; H01L 2224/73204

(57) ABSTRACT

An electronic component-incorporating substrate includes a first substrate, a second substrate, a spacer member, an electronic component, and an encapsulation resin. The first substrate includes a first connection pad. The second substrate includes a second connection pad that faces the first connection pad. The spacer member electrically connects the first connection pad and the second connection pad. The electronic component is mounted on the first substrate and is disposed between the first substrate and the second substrate. The encapsulation resin fills a gap between the first substrate and the second substrate and encapsulates the electronic component. The spacer member includes a spherical solder core ball and a solder layer that covers a circumference of the solder core ball. A melting point of the solder layer is lower than a melting point of the solder core ball.

### CROSS-REFERENCE TO RELATED APPLICATIONS

This application is based upon and claims the benefit of priority from prior Japanese Patent Application No. 2023-185341, filed on Oct. 30, 2023, the entire contents of which are incorporated herein by reference.

### BACKGROUND

### 1. Field

The following description relates to an electronic component-incorporating substrate and a method for manufacturing an electronic component-incorporating substrate.

### 2. Description of Related Art

An electronic component-incorporating substrate that incorporates electronic components between a lower substrate and an upper substrate has been proposed (refer to Japanese Laid-Open Patent Publication Nos. 2008-135781 and 2008-10885). In this type of electronic component-incorporating substrate, the upper substrate is fixed to the lower substrate by a spacer member that maintains the distance between the upper substrate to the lower substrate. Then, the gap between the lower substrate and the upper substrate is filled with an encapsulation resin.

Such a spacer member in the electronic component-incorporating substrate includes a copper core solder ball. The copper core solder ball is formed by covering a copper core ball with a solder layer. In the copper core solder ball, the copper core ball functions as a spacer, and the solder layer functions as a bonding material. In a state in which the copper core solder ball is sandwiched between a connection pad of the upper substrate and a connection pad of the lower substrate, reflow soldering is performed to solder the connection pad of the upper substrate to the connection pad of the lower substrate. In this case, the copper core ball in the solder layer is sandwiched between the connection pad of the upper substrate and the connection pad of the lower substrate, thereby acting as a spacer.

In a typical electronic component-incorporating substrate, if adhesion between the copper core ball and the solder layer of the spacer member is insufficient, a crack may be formed in the interface between the copper core ball and the solder layer. Such formation of a crack inside the spacer member may lower the electrical connection reliability between the lower substrate and the upper substrate.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, an electronic component-incorporating substrate includes a first substrate, a second substrate, a spacer member, an electronic component, and an encapsulation resin. The first substrate includes a first connection pad. The second substrate includes a second connection pad that faces the first connection pad. The spacer member electrically connects the first connection pad and the second connection pad. The electronic component is mounted on the first substrate and is disposed between the first substrate and the second substrate. The encapsulation resin fills a gap between the first substrate and the second substrate and encapsulates the electronic component. The spacer member includes a spherical solder core ball and a solder layer that covers a circumference of the solder core ball. A melting point of the solder layer is lower than a melting point of the solder core ball.

Other features and aspects will be apparent from the following detailed description, the drawings, and the claims.

### BRIEF DESCRIPTION OF THE DRAWINGS

FIG. 1 is a schematic cross-sectional view of an electronic component-incorporating substrate in accordance with an embodiment.

FIGS. 2, 3, 4, 5, and 6 are schematic cross-sectional views illustrating a method for manufacturing the electronic component-incorporating substrate illustrated in FIG. 1.

FIG. 7 is a schematic cross-sectional view of an electronic component-incorporating substrate of a modified example.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

This description provides a comprehensive understanding of the methods, apparatuses, and/or systems described. Modifications and equivalents of the methods, apparatuses, and/or systems described are apparent to one of ordinary skill in the art. Sequences of operations are exemplary, and may be changed as apparent to one of ordinary skill in the art, with the exception of operations necessarily occurring in a certain order. Descriptions of functions and constructions that are well known to one of ordinary skill in the art may be omitted.

Exemplary embodiments may have different forms, and are not limited to the examples described. However, the examples described are thorough and complete, and convey the full scope of the disclosure to one of ordinary skill in the art.

An embodiment will now be described with reference to the drawings.

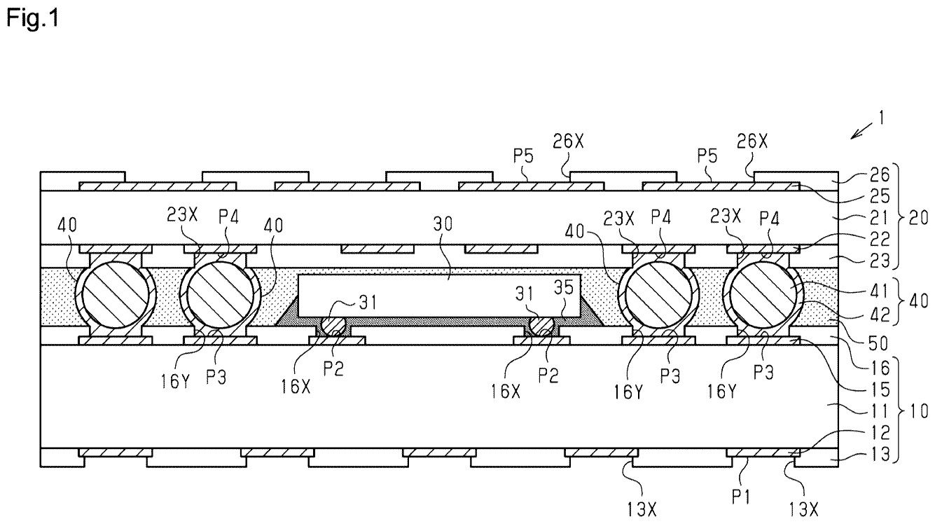

In the accompanying drawings, elements are illustrated for simplicity and clarity and have not necessarily been drawn to scale. To facilitate understanding, hatching lines may not be illustrated or may be replaced by shadings in the cross-sectional views. In this specification, a plan view refers to a view taken in a vertical direction (e.g., top-bottom direction in FIG. 1), and a planar shape refers to a shape of a subject as viewed in the vertical direction. Further, in this specification, upward, downward, leftward, and rightward directions refer to directions when the drawings are oriented to allow the reference characters denoting members to be read properly. In this specification, the term “face” is used to indicate that surfaces or members are arranged in front of each other. In this case, the objects do not have to be entirely in front of each other and may be partially in front of each other. Further, “face” includes both a case in which another member is located between two objects and a case in which no member is located between two objects. Furthermore, unless otherwise specified, a numerical range of “X1 to X2”, defined by the upper limit value X1 and the lower limit value X2, corresponds to a range that is greater than or equal to X1 and less than or equal to X2 and may also be represented by the expression of “between X1 and X2, inclusive.”

### Overall Structure of Electronic Component-Incorporating Substrate 1

As illustrated in FIG. 1, an electronic component-incorporating substrate 1 includes a first substrate 10, a second substrate 20, a semiconductor chip 30, an underfill resin 35, a spacer member 40, and an encapsulation resin 50.

### Structure of First Substrate 10

The first substrate 10 includes a substrate body 11. A wiring layer 12 and a solder resist layer 13 are stacked in this order on a lower surface of the substrate body 11. A wiring layer 15 and a solder resist layer 16 are stacked in this order on an upper surface of the substrate body 11.

The substrate body 11 may be a wiring structure in which insulating resin layers and wiring layers are alternately stacked. For example, such a wiring structure may include a core substrate, but does not have to include a core substrate. The material of the insulating resin layers may be, for example, a thermosetting insulating resin. The thermosetting insulating resin may be, for example, an insulating resin, such as an epoxy resin, a polyimide resin, or a cyanate resin. Furthermore, the material of the insulating resin layers may be, for example, an insulating resin including a photosensitive resin, such as a phenol-based resin or a polyimide-based resin, as a main component. The insulating resin layers may each contain, for example, a filler such as silica or alumina.

The material of the wiring layers of the substrate body 11 and the material of the wiring layers 12 and 15 may be, for example, copper (Cu) or a copper alloy. The material of the solder resist layers 13 and 16 may be, for example, an insulating resin including a photosensitive resin, such as a phenol-based resin or a polyimide-based resin, as a main component. The solder resist layers 13 and 16 may each contain, for example, a filler such as silica or alumina.

The wiring layer 12 is formed on the lower surface of the substrate body 11. The wiring layer 12 is the lowermost wiring layer of the first substrate 10.

The solder resist layer 13 is arranged on the lower surface of the substrate body 11 and covers the wiring layer 12. The solder resist layer 13 is the outermost insulating layer (here, lowermost insulating layer) of the first substrate 10.

The solder resist layer 13 includes openings 13X that expose parts of a lower surface of the wiring layer 12 as external connection pads P1. The external connection pads P1 are configured to be connected to external connection terminals used when mounting the electronic component-incorporating substrate 1 on a mounting substrate such as a motherboard.

A surface-processed layer is formed, if necessary, on the lower surface of the wiring layer 12 exposed at the bottom of each opening 13X. Examples of the surface-processed layer include a gold (Au) layer, a nickel (Ni) layer/Au layer (metal layer in which Ni layer serves as bottom layer, and Au layer is formed on Ni layer), an Ni layer/palladium (Pd) layer/Au layer (metal layer in which Ni layer serves as bottom layer, and Pd layer and Au layer are sequentially formed on Ni layer), or the like. Further examples of the surface-processed layer include a Ni layer/Pd layer (metal layer in which Ni layer serves as bottom layer, and Pd layer is formed on Ni layer), a Pd layer/Au layer (metal layer in which Pd layer serves as bottom layer, and Au layer is formed on Pd layer), or the like. An Au layer is a metal layer of Au or an Au alloy, an Ni layer is a metal layer of Ni or an Ni alloy, and a Pd layer is a metal layer of Pd or a Pd alloy. Each of the Au layer, the Ni layer, and the Pd layer may be, for example, a metal layer (electroless plating layer) formed by electroless plating or a metal layer (electrolytic plating layer) formed by electrolytic plating. Alternatively, the surface-processed layer may be an organic solderability preservative (OSP) film formed by performing an oxidation-resisting process, such as an OSP process, on the lower surface of the wiring layer 12 exposed from the openings 13X. The OSP film may be, for example, an organic coating of an azole compound or an imidazole compound. When a surface-processed layer is formed on the lower surface of the wiring layer 12, the surface-processed layer functions as the external connection pads P1.

In the example illustrated in FIG. 1, external connection terminals are arranged on the external connection pads P1. Alternatively, the wiring layer 12 exposed from the openings 13X or a surface-processed layer (if any) formed on the wiring layer 12 may be used as external connection terminals.

The wiring layer 15 is arranged on a mounting surface (upper surface side in FIG. 1) of the first substrate 10 on which the semiconductor chip 30 is mounted. The wiring layer 15 is formed on the upper surface of the substrate body 11. The wiring layer 15 is electrically connected to the wiring layer 12 through the wiring layers and through-electrodes (not illustrated) formed in the substrate body 11.

The wiring layer 15 includes pads P2 and connection pads P3. The pads P2 are for mounting an electronic component and are electrically connectable to bumps 31 of the semiconductor chip 30. The connection pads P3 are for electrically connecting the first substrate 10 and the second substrate 20. Although not illustrated in plan view, for example, the pads P2 are arrayed in a matrix form in a mounting region where the semiconductor chip 30 is mounted in plan view in correspondence with arrangement of the bumps 31 of the semiconductor chip 30. Each pad P2 is, for example, circular in plan view.

The connection pads P3 are disposed outside the mounting region of the semiconductor chip 30 in plan view. The connection pads P3 surround the periphery of the semiconductor chip 30 in plan view. Although not illustrated in plan view, the connection pads P3 are arranged in multiple rows (two rows in example illustrated in FIG. 1) and surround the periphery of the semiconductor chip 30. Each connection pad P3 is, for example, circular in plan view.

The solder resist layer 16 is arranged on the upper surface of the substrate body 11 and covers the wiring layer 15. The solder resist layer 16 is the outermost insulating layer (here, uppermost insulating layer) of the first substrate 10.

The solder resist layer 16 includes openings 16X and openings 16Y. The openings 16X expose parts of an upper surface of the wiring layer 15 as the pads P2. The openings 16Y expose parts of the upper surface of the wiring layer 15 as the connection pads P3. A surface-processed layer is formed, if necessary, on the wiring layer 15 exposed from the openings 16X and 16Y, that is, the pads P2 and the connection pads P3. Examples of the surface-processed layer include an OSP film or a metal layer, such as an Au layer, an Ni layer/Au layer, an Ni layer/Pd layer/Au layer, an Ni layer/Pd layer, or a Pd/Au layer. When a surface-processed layer is formed on the upper surface of the wiring layer 15, the surface-processed layer functions as the pads P2 or the connection pads P3.

### Structure of Semiconductor Circuit 30

The semiconductor chip 30 includes the bumps 31 formed on a circuit formation surface (lower surface in FIG. 1) of the semiconductor chip 30. The semiconductor chip 30 is mounted on an upper surface of the first substrate 10. The semiconductor chip 30 is flip-chip-mounted on the upper surface of the first substrate 10. The semiconductor chip 30 is electrically connected to the pads P2 of the first substrate 10 through the bumps 31. Accordingly, the semiconductor chip 30 is electrically connected to the wiring layer 15 of the first substrate 10 through the bumps 31.

The semiconductor chip 30 may be, for example, a logic chip, such as a central processing unit (CPU) chip or a graphics processing unit (GPU) chip. Furthermore, the semiconductor chip 30 may be, for example, a memory chip, such as a dynamic random access memory (DRAM) chip, a static random access memory (SRAM) chip, or a flash memory chip. Alternatively, multiple semiconductor chips 30 including a combination of logic chips and memory chips may be mounted on the first substrate 10.

The semiconductor chip 30 is, for example, rectangular in plan view. The semiconductor chip 30 may have a size of, for example, approximately 3 mm×3 mm to 12 mm×12 mm in plan view. The semiconductor chip 30 may have a thickness of, for example, approximately 50 μm to 100 μm.

The bumps 31 may be, for example, gold bumps or solder bumps. The material of solder bumps may be an alloy including lead (Pb), an alloy of tin (Sn) and Au, an alloy of Sn and Cu, an alloy of Sn and silver (Ag), an alloy of Sn, Ag, and Cu, or the like. The bumps 31 may have a thickness of, for example, approximately 20 μm to 70 μm.

The underfill resin 35 fills the gap between the upper surface of the first substrate 10 and a lower surface of the semiconductor chip 30. The material of the underfill resin 35 may be, for example, an insulating resin, such as an epoxy-based resin.

### Structure of Second Substrate 20

The second substrate 20 includes a substrate body 21. A wiring layer 22 and a solder resist layer 23 are stacked in this order on a lower surface of the substrate body 21. A wiring layer 25 and a solder resist layer 26 are stacked in this order on an upper surface of the substrate body 21.

The substrate body 21 may be a wiring structure in which insulating resin layers and wiring layers are alternately stacked. For example, such a wiring structure may include a core substrate, but does not have to include a core substrate. The material of the insulating resin layers may be, for example, a thermosetting insulating resin. The thermosetting insulating resin may be, for example, an insulating resin, such as an epoxy resin, a polyimide resin, or a cyanate resin. Furthermore, the material of the insulating resin layers may be, for example, an insulating resin including a photosensitive resin, such as a phenol-based resin or a polyimide-based resin, as a main component. The insulating resin layers may each contain, for example, a filler such as silica or alumina.

The material of the wiring layers of the substrate body 21 and the material of the wiring layers 22 and 25 may be, for example, copper or a copper alloy. The material of the solder resist layers 23 and 26 may be, for example, an insulating resin including a photosensitive resin, such as a phenol-based resin or a polyimide-based resin, as a main component. The solder resist layers 23 and 26 may each contain, for example, a filler such as silica or alumina.

The wiring layer 22 is formed on the lower surface of the substrate body 21 that faces the first substrate 10. The wiring layer 22 is the lowermost wiring layer of the second substrate 20. The wiring layer 22 includes connection pads P4 for electrically connecting the first substrate 10 and the second substrate 20. Each of the connection pads P4 is electrically connected to a corresponding one of the connection pads P3 arranged on the first substrate 10 by the spacer member 40.

Each of the connection pads P4 faces the corresponding one of the connection pads P3 arranged on the first substrate 10. The connection pads P4 surround the periphery of the semiconductor chip 30 in plan view. Although not illustrated in plan view, the connection pads P4 are arranged in multiple rows (two rows in example illustrated in FIG. 1) and surround the periphery of the semiconductor chip 30. Each connection pad P4 is, for example, circular in plan view.

The solder resist layer 23 is arranged on the lower surface of the substrate body 21 and covers the wiring layer 22. The solder resist layer 23 is the outermost insulating layer (here, lowermost insulating layer) of the second substrate 20.

The solder resist layer 23 includes openings 23X that expose parts of a lower surface of the wiring layer 22 as the connection pads P4. A surface-processed layer is formed, if necessary, on the wiring layer 22 exposed from the openings 23X, that is, the connection pads P4. Examples of the surface-processed layer include an OSP film or a metal layer, such as an Au layer, an Ni layer/Au layer, an Ni layer/Pd layer/Au layer, an Ni layer/Pd layer, or a Pd/Au layer. When a surface-processed layer is formed on the lower surface of the wiring layer 22, the surface-processed layer functions as the connection pads P4.

The wiring layer 25 is formed on the upper surface of the substrate body 21 on which another electronic component, which is not the semiconductor chip 30, is mounted. The wiring layer 25 is electrically connected to the wiring layer 22 through the wiring layers and through-electrodes (not illustrated) formed in the substrate body 21.

The wiring layer 25 includes component connection pads P5 configured to be electrically connected to the other electronic component, such as a semiconductor chip or a passive element, that is not the semiconductor chip 30. Each component connection pad P5 is, for example, circular in plan view.

The solder resist layer 26 is arranged on the upper surface of the substrate body 21 and covers the wiring layer 25. The solder resist layer 26 is the outermost insulating layer (here, uppermost insulating layer) of the second substrate 20.

The solder resist layer 26 includes openings 26X that expose parts of an upper surface of the wiring layer 25 as the component connection pads P5. A surface-processed layer is formed, if necessary, on the wiring layer 25 exposed from the openings 26X, that is, the component connection pads P5. Examples of the surface-processed layer include an OSP film or a metal layer, such as an Au layer, an Ni layer/Au layer, an Ni layer/Pd layer/Au layer, an Ni layer/Pd layer, or a Pd/Au layer. When a surface-processed layer is formed on the upper surface of the wiring layer 25, the surface-processed layer functions as the component connection pads P5.

### Structure of Spacer Member 40

The spacer members 40 electrically connect the connection pads P3 of the first substrate 10 and the connection pads P4 of the second substrate 20. The spacer members 40 are joined to both the connection pads P3 and P4. That is, the spacer members 40 are disposed between the first substrate 10 and the second substrate 20. Each of the spacer members 40 includes a first end joined to the connection pad P3 and a second end joined to the connection pad P4. The spacer member 40 has a functionality of a connection terminal that electrically connects the connection pad P3 and the connection pad P4 and a functionality of a spacer that holds the distance, or a separation distance, between the first substrate 10 and the second substrate 20 at a specified value.

The spacer member 40 includes a spherical solder core ball 41 and a solder layer 42 that covers the circumference of the solder core ball 41. The solder layer 42 is formed of solder having a melting point that is lower than that of the solder core ball 41. The melting point of the solder layer 42, which is a low-melting-point solder layer, may be, for example, approximately 100° C. to 200° C. The melting point of the solder layer 42 may be lower than the melting point of the solder core ball 41 by 20° C. or greater. The material of the solder layer 42 may be, for example, Pb-free solder of a Sn-bismuth (Bi) base or a Sn-indium (In) base. The solder core ball 41 is formed of solder having a melting point that is higher than that of the solder layer 42. The melting point of the solder core ball 41 may be, for example, approximately 220° C. to 280° C. The material of the solder core ball 41 may be, for example, Pb-free solder of a Sn—Ag base or a Sn-antimony (Sb) base.

In the spacer member 40, the solder layer 42 functions as a bonding material. The spacer member 40 is bonded to the connection pad P3 by the solder layer 42 and is bonded to the connection pad P4 by the solder layer 42. The solder layer 42 is, for example, melted by a heating process performed during the manufacture of the electronic component-incorporating substrate 1, and then solidified to join the connection pads P3 and P4. The solder layer 42 fills, for example, the opening 16Y in the solder resist layer 16 and the opening 23X in the solder resist layer 23.

In the spacer member 40, the solder core ball 41 functions as a spacer. The solder core ball 41 is, for example, not melted and is maintained in a spherical shape during the heating process in which the solder layer 42 is melted. Accordingly, the height (diameter) of the solder core ball 41 defines the height of the gap between the first substrate 10 and the second substrate 20. Such a height of the solder core ball 41 is, for example, set to be greater than the thickness of the semiconductor chip 30. In an example, the height of the solder core ball 41 is set to be greater than a total sum of the thickness of the semiconductor chip 30 and the thickness of the bump 31. The height of the solder core ball 41 may be, for example, approximately 100 μm to 200 μm.

### Structure of Encapsulation Resin 50

The encapsulation resin 50 fills the gap between the first substrate 10 and the second substrate 20. The encapsulation resin 50 encapsulates the semiconductor chip 30 disposed between the first substrate 10 and the second substrate 20. The encapsulation resin 50 may encapsulate the semiconductor chip 30 by partially or entirely covering the semiconductor chip 30. In the example illustrated in FIG. 1, the underfill resin 35 is disposed between the first substrate 10 and the semiconductor chip 30 to cover a lower part of the semiconductor chip 30, the encapsulation resin 50 encapsulates the semiconductor chip 30 by covering an upper part (that is, remaining part) of the semiconductor chip 30 (in FIG. 1, upper surface and upper portion of side surface of the semiconductor chip 30). The encapsulation resin 50 fixes the second substrate 20 to the first substrate 10 and encapsulates the semiconductor chip 30. In this manner, the encapsulation resin 50 has a functionality of an adhesive that bonds the first substrate 10 and the second substrate 20 and a functionality of a protection layer that protects the semiconductor chip 30. The material of the encapsulation resin 50 may be, for example, an insulating resin, such as an epoxy-based resin or a polyimide-based resin.

### Method for Manufacturing Electronic Component-Incorporating Substrate 1

A method for manufacturing the electronic component-incorporating substrate 1 will now be described.

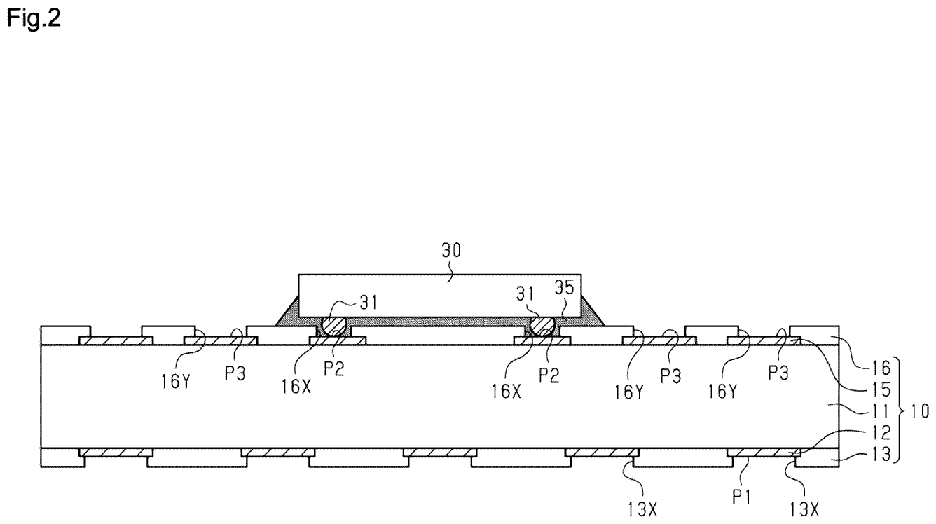

First, in the step illustrated in FIG. 2, the first substrate 10 is prepared. The first substrate 10 includes the substrate body 11, the wiring layer 12 and the solder resist layer 13 stacked on the lower surface of the substrate body 11, and the wiring layer 15 and the solder resist layer 16 stacked on the upper surface of the substrate body 11. The first substrate 10 may be manufactured by a known manufacturing process, and thus such a process will not be described in detail.

Then, the semiconductor chip 30 is flip-chip-mounted on the upper surface of the first substrate 10. In the example illustrated in FIG. 2, the bumps 31 of the semiconductor chip 30 are flip-chip-bonded to the pads P2 of the first substrate 10. Subsequently, the underfill resin 35 is added to fill the gap between the upper surface of the first substrate 10 (upper surface of solder resist layer 16 in FIG. 2) and the lower surface of the semiconductor chip 30, and then cured.

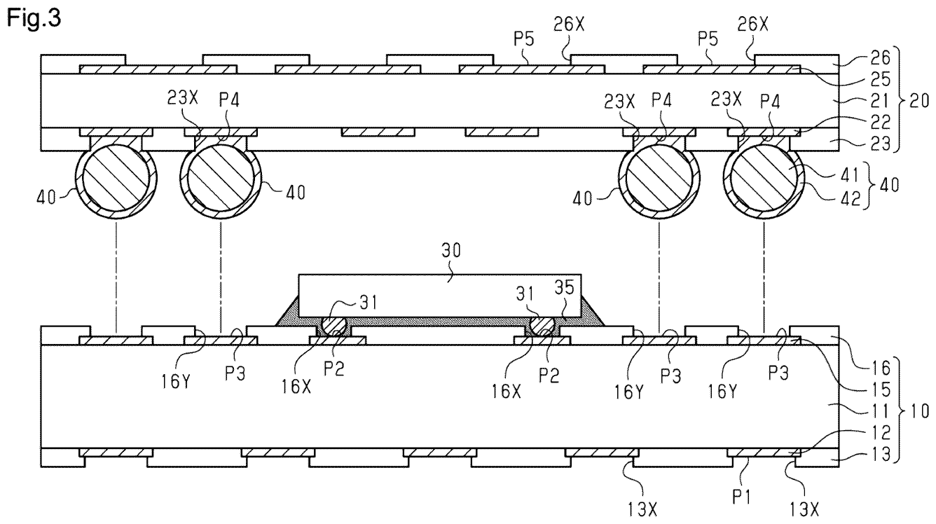

In the step illustrated in FIG. 3, the second substrate 20 is prepared. The second substrate 20 includes the substrate body 21, the wiring layer 22 and the solder resist layer 23 stacked on the lower surface of the substrate body 21, and the wiring layer 25 and the solder resist layer 26 stacked on the upper surface of the substrate body 21. The second substrate 20 may be manufactured by a known manufacturing process, and thus such a process will not be described in detail.

Then, the spacer members 40 are arranged on the connection pads P4 of the second substrate 20. The spacer members 40 each include the solder core ball 41 and the solder layer 42 that covers the circumference of the solder core ball 41. For example, the spacer members 40 are arranged after flux is applied to the connection pads P4. Subsequently, reflow soldering is performed at a first temperature (for example, approximately 200° C.) at which only the solder layer 42 of the spacer member 40 is melted to bond the solder layer 42 to the corresponding connection pad P4. In particular, only the solder layer 42 is melted at the first temperature that is higher than the melting point of the solder layer 42 and lower than the melting point of the solder core ball 41, and then the solder layer 42 is cooled and solidified. This bonds the solder layer 42 to the connection pad P4. In this case, since the first temperature is lower than the melting point of the solder core ball 41, the solder core ball 41 is not melted and only the solder layer 42 is melted and solidified.

The second substrate 20 is positioned above the first substrate 10 so that the spacer members 40 face the upper surface of the first substrate 10. In this case, the first substrate 10 and the second substrate 20 are positioned so that the connection pads P3 and the connection pads P4 face toward each other.

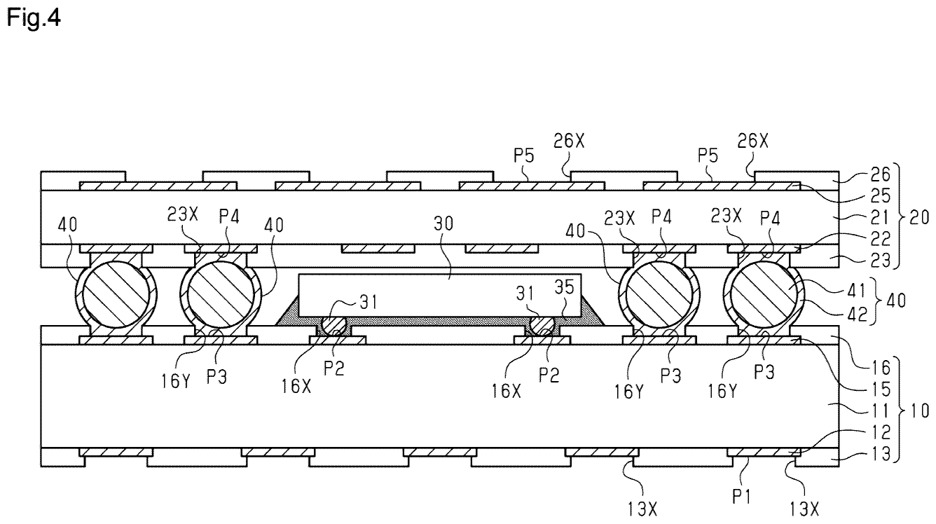

In the step illustrated in FIG. 4, the spacer members 40 are bonded to the connection pads P3. The second substrate 20 is arranged on the first substrate 10 with the spacer members 40 sandwiched in between, for example, after flux is applied to the connection pads P3. As a result, the spacer members 40 are disposed between the solder resist layer 16 of the first substrate 10 and the solder resist layer 23 of the second substrate 20, and a space (gap) is formed by such spacer members 40. Then, reflow soldering is performed on the first substrate 10 and the second substrate 20, which are stacked as described above, at the first temperature (for example, approximately 200° C.) at which only the solder layer 42 of the spacer member 40 is melted. In this case, since the first temperature is lower than the melting point of the solder core ball 41, the solder core ball 41 is not melted and only the solder layer 42 is melted and solidified. Thus, the solder core ball 41 is maintained in a spherical state, and the solder layer 42 is bonded to the connection pads P3 and P4. In this manner, the spacer members 40 fix the second substrate 20 to the first substrate 10 and electrically connect the connection pads P3 and the connection pads P4. In the step illustrated in FIG. 4, reflow soldering is performed while the second substrate 20 is being pressed toward the first substrate 10. In this case, the solder core balls 41 of the spacer members 40, that are not melted and are maintained in a spherical state, act as spacers. This maintains the distance between the first substrate 10 and the second substrate 20 in accordance with the diameter of the solder core balls 41.

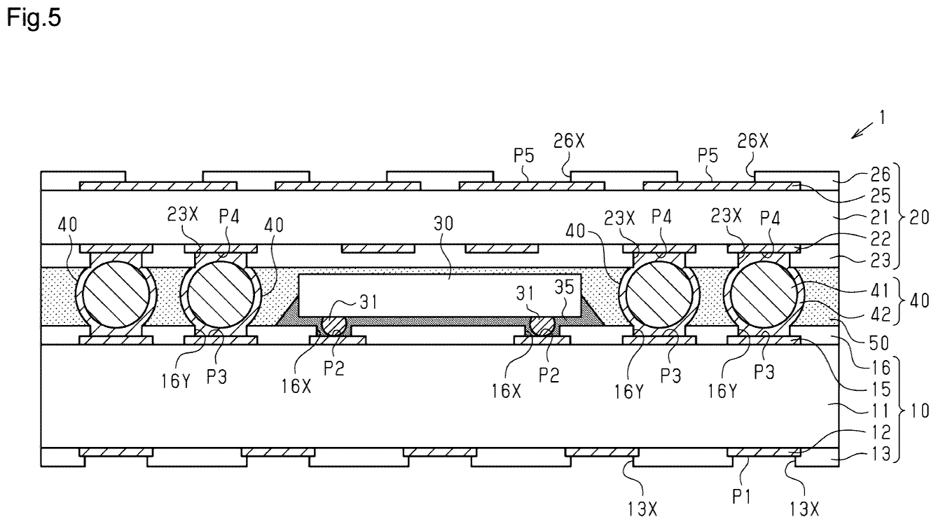

In the step illustrated in FIG. 5, the encapsulation resin 50 is formed to fill the gap between the first substrate 10 and the second substrate 20, that is, the gap between the solder resist layer 16 and the solder resist layer 23. The encapsulation resin 50 encapsulates the semiconductor chip 30 disposed between the first substrate 10 and the second substrate 20. The encapsulation resin 50 may be formed by, for example, a resin molding process. When a thermosetting mold resin is used as the material of the encapsulation resin 50, for example, a pressure (for example, 5 MPa to 10 MPa) is applied to a mold that accommodates the structural body illustrated in FIG. 4, and a liquidized mold resin is added into the mold. The mold resin is heated at a temperature of approximately 180° C. and then cured to form the encapsulation resin 50. After an encapsulation process is completed, the structural body including the encapsulation resin 50 is removed from the mold. The mold may be filled with the mold resin by, for example, transfer molding, compression molding, injection molding, or the like.

The heating temperature in the step illustrated in FIG. 5 is set to be lower than the melting point of the solder core ball 41. Thus, the solder core ball 41 is maintained in a spherical state without being melted in this step. Accordingly, after this step, an interface is present between the solder core ball 41 and the solder layer 42 in each spacer member 40.

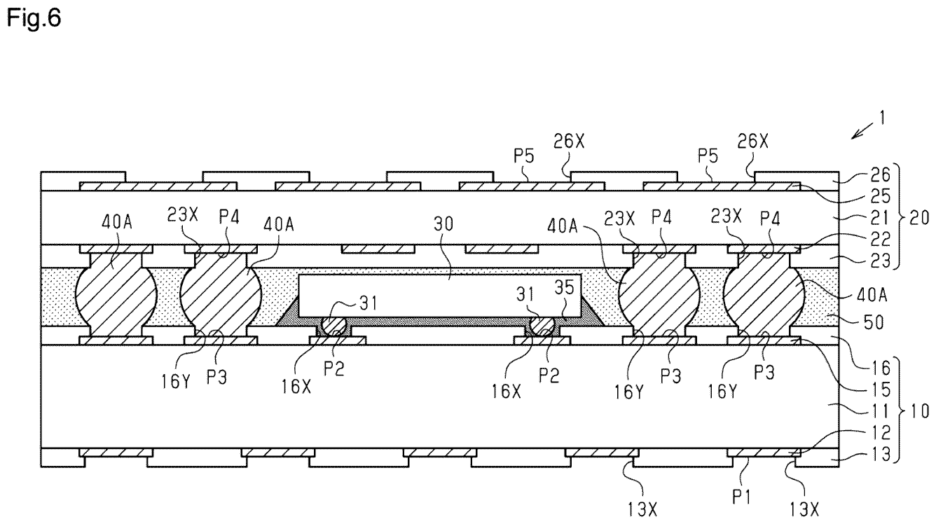

Thereafter, heating is performed at a second temperature that is higher than the melting point of the solder core ball 41 so as to integrate the solder core ball 41 with the solder layer 42. In particular, the structural body illustrated in FIG. 5 is heated at the second temperature to melt both the solder core ball 41 and the solder layer 42 so as to blend the two types of solder and eliminate the interface between the solder core ball 41 and the solder layer 42. Accordingly, the solder core ball 41 is integrated with the solder layer 42. As a result, single-layered spacer members 40A are formed as illustrated in FIG. 6. In this manner, the step illustrated in FIG. 6 blends the two different types of solder, namely, the solder core ball 41 and the solder layer 42 illustrated in FIG. 5, so that a crack will not be included inside the spacer member 40A.

The present embodiment has the following advantages.

(1) The electronic component-incorporating substrate 1 includes the first substrate 10, the second substrate 20, and the spacer members 40. The first substrate 10 includes the connection pads P3. The second substrate 20 includes the connection pads P4 that face the connection pads P3. The spacer members 40 electrically connect the connection pads P3 and the connection pads P4. The electronic component-incorporating substrate 1 includes the semiconductor chip 30 and the encapsulation resin 50. The semiconductor chip 30 is mounted on the first substrate 10 and is disposed between the first substrate 10 and the second substrate 20. The encapsulation resin 50 fills the gap between the first substrate 10 and the second substrate 20 and encapsulates the semiconductor chip 30. The spacer members 40 each include the spherical solder core ball 41 and the solder layer 42 that covers the circumference of the solder core ball 41. The melting point of the solder layer 42 is lower than the melting point of the solder core ball 41.

With this structure, the spherical solder core ball 41 of the spacer member 40 functions as a spacer that holds the separation distance between the first substrate 10 and the second substrate 20 at a specified value. Further, the solder layer 42 of the spacer member 40 functions as a bonding material that bonds the spacer member 40 to the connection pads P3 and P4. A manufacturing error, a manufacturing condition, or the like during the manufacture of the electronic component-incorporating substrate 1 may cause a crack to be formed in the interface between the solder core ball 41 and the solder layer 42. In this respect, the spacer member 40 of the present embodiment is formed by two types of solder having different melting points, that is, the solder core ball 41 and the solder layer 42. Thus, when heating is performed at the second temperature, which is higher than the melting point of the solder layer 42 and the melting point of the solder core ball 41, the two types of solder will be blended. Accordingly, even if a crack is formed in the interface between the solder core ball 41 and the solder layer 42, the molten solder may spread and fill the crack as the two types of solder blend together and eliminate the crack. Therefore, a crack will not be included inside the spacer member 40A in which the solder core ball 41 is integrated with the solder layer 42. This maintains the electrical connection reliability between the connection pad P3 and the connection pad P4, which are electrically connected by the spacer member 40A.

(2) The melting point of the solder layer 42 is lower than the melting point of the solder core ball 41 by 20° C. or greater. With this configuration, even if the melting point of the solder core ball 41 and the melting point of the solder layer 42 are slightly deviated from target values due to a manufacturing error or the like, only the solder layer 42 will be melted when reflow soldering is performed at the first temperature.

(3) The method for manufacturing the electronic component-incorporating substrate 1 includes bonding the solder layer 42 to the connection pads P3 and P4 by performing reflow soldering at the first temperature that is higher than the melting point of the solder layer 42 and lower than the melting point of the solder core ball 41. With this configuration, the solder core ball 41 will not be melted by the reflow soldering performed at the first temperature and will be maintained in a spherical state. Therefore, in a structural body in a state before the encapsulation resin 50 is formed, the solder core ball 41 may act as a spacer that holds the separation distance between the first substrate 10 and the second substrate 20 at a specified value.

(4) The above method further includes, after the encapsulation resin 50 is formed, a step of integrating the solder core ball 41 with the solder layer 42 by performing heating at the second temperature that is higher than the melting point of the solder core ball 41. With this configuration, the solder core ball 41 and the solder layer 42 are melted and integrated with each other after the encapsulation resin 50 is formed. The encapsulation resin 50 fixes the first substrate 10 and the second substrate 20 and holds the separation distance between the first substrate 10 and the second substrate 20 at a specified value. Therefore, when the solder core ball 41 acting as a spacer is melted, the formed encapsulation resin 50 acts as another spacer. This appropriately maintains the separation distance between the first substrate 10 and the second substrate 20 at a specified value even when the solder core ball 41 is melted.

### Other Embodiments

The above embodiment may be modified as described below. The above embodiment and the following modifications may be combined as long as the combined modifications remain technically consistent with each other.

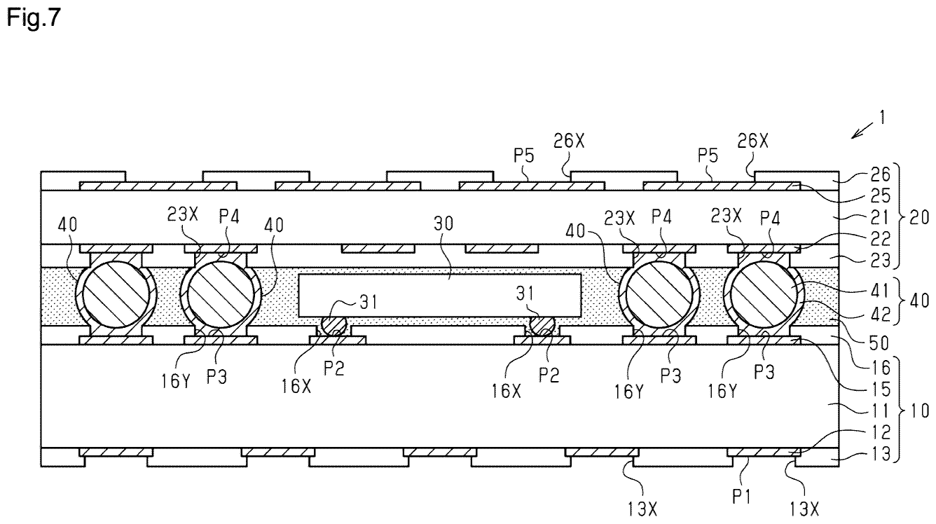

As illustrated in FIG. 7, the underfill resin 35 may be omitted, and the encapsulation resin 50 may seal the gap between the first substrate 10 and the semiconductor chip 30. In this case, the encapsulation resin 50 encapsulates the semiconductor chip 30 by entirely covering the semiconductor chip 30. Thus, the gap between the first substrate 10 and the semiconductor chip 30 is filled with the encapsulation resin 50, and the bumps 31 are encapsulated by the encapsulation resin 50.

When the bumps 31 are formed by solder, the melting point of the bump 31 may be equal to the melting point of the solder core ball 41 or higher than the melting point of the solder core ball 41. In this case, the melting point of the solder layer 42 is lower than the melting point of the bump 31. With such a setting, the bumps 31 will not be melted when the solder layer 42 of the spacer member 40 is melted to connect the first substrate 10 and the second substrate 20. Therefore, even when the underfill resin 35 is omitted and the encapsulation resin 50 seals the gap between the first substrate 10 and the semiconductor chip 30, as in the modified example illustrated in FIG. 7, the electrical connection reliability between the bumps 31 and the pads P2 will be maintained. This ensures the connection reliability of the semiconductor chip 30.

The structure of the first substrate 10 in the above embodiment may be changed. For example, the solder resist layer 13 may be omitted. For example, the solder resist layer 16 may be omitted.

The structure of the second substrate 20 in the above embodiment may be changed. For example, the solder resist layer 23 may be omitted. For example, the solder resist layer 26 may be omitted.

In the electronic component-incorporating substrate 1 of the above embodiment, a plurality of electronic components may be mounted on the first substrate 10.

In the above embodiment, the semiconductor chip 30 is mounted on the first substrate 10. Instead, a passive element, such as a capacitor or an inductor, may be mounted on the first substrate 10.

In the above embodiment, the electronic component-incorporating substrate 1 has a structure in which two substrates, namely, the first substrate 10 and the second substrate 20, are stacked with the spacer member 40 arranged in between. Alternatively, the electronic component-incorporating substrate 1 may have a structure in which three or more substrates are stacked with the spacer members 40 arranged in between.

### Clauses

This disclosure further encompasses the following embodiments.

1. A method for manufacturing an electronic component-incorporating substrate, the method including:
preparing a first substrate including a first connection pad;
mounting an electronic component on an upper surface of the first substrate;
preparing a second substrate including a second connection pad;
mounting the second substrate on the first substrate in a state in which a spacer member is arranged between the first connection pad and the second connection pad, the spacer member including a spherical solder core ball and a solder layer that covers a circumference of the solder core ball;
bonding the solder layer to the first connection pad and the second connection pad by performing reflow soldering at a first temperature at which only the solder layer of the spacer member is melted; and
forming an encapsulation resin that fills a gap between the first substrate and the second substrate and encapsulates the electronic component disposed between the first substrate and the second substrate, in which
a melting point of the solder layer is lower than a melting point of the solder core ball, and
the first temperature is higher than the melting point of the solder layer and lower than the melting point of the solder core ball.

2. The method according to clause 1, further including:
after the forming the encapsulation resin, integrating the solder core ball with the solder layer by performing heating at a second temperature that is higher than the melting point of the solder core ball.

3. The method according to clause 1, further including:
before the mounting the second substrate on the first substrate,
   mounting the spacer member on the second connection pad; and
   bonding the solder layer to the second connection pad by performing reflow soldering at the first temperature.

Various changes in form and details may be made to the examples above without departing from the spirit and scope of the claims and their equivalents. The examples are for the sake of description only, and not for purposes of limitation. Descriptions of features in each example are to be considered as being applicable to similar features or aspects in other examples. Suitable results may be achieved if sequences are performed in a different order, and/or if components in a described system, architecture, device, or circuit are combined differently, and/or replaced or supplemented by other components or their equivalents. The scope of the disclosure is not defined by the detailed description, but by the claims and their equivalents. All variations within the scope of the claims and their equivalents are included in the disclosure.

What is claimed is:

1. An electronic component-incorporating substrate, comprising:
a first substrate including a first connection pad;
a second substrate including a second connection pad that faces the first connection pad;
a spacer member electrically connecting the first connection pad and the second connection pad;
an electronic component mounted on the first substrate and disposed between the first substrate and the second substrate; and
an encapsulation resin filling a gap between the first substrate and the second substrate and encapsulating the electronic component, wherein
the spacer member includes a spherical solder core ball and a solder layer that covers a circumference of the solder core ball, and
a melting point of the solder layer is lower than a melting point of the solder core ball.

2. The electronic component-incorporating substrate according to claim 1, wherein the melting point of the solder layer is lower than the melting point of the solder core ball by 20° C. or greater.

3. The electronic component-incorporating substrate according to claim 1, wherein
the melting point of the solder layer is between 100° C. to 200° C., inclusive, and
the melting point of the solder core ball is between 220° C. and 280° C., inclusive.

4. The electronic component-incorporating substrate according to claim 1, wherein
a material of the solder layer is lead-free solder of a tin-bismuth base or a tin-indium base, and
a material of the solder core ball is lead-free solder of a tin-silver base or a tin-antimony base.

5. The electronic component-incorporating substrate according to claim 1, wherein
the electronic component includes a bump that electrically connects the electronic component and the second connection pad, and
a melting point of the bump is equal to the melting point of the solder core ball or higher than the melting point of the solder core ball.
